(19) United States
(12) Patent Application Publication
(10) Pub. No.: US 2013/0327265 A1
(43) Pub. Date: Dec. 12, 2013

(54) METHOD FOR PRODUCING SILICON CARBIDE CRYSTAL

(71) Applicant: SUMITOMO ELECTRIC INDUSTRIES, LTD., Osaka-shi (JP)

(72) Inventors: Hiroki INOUE, Itami-shi, Hyogo (JP); Makoto SASAKI, Itami-shi, Hyogo (JP); Shinsuke FUJIWARA, Itami-shi, Hyogo (JP)

(73) Assignee: SUMITOMO ELECTRIC INDUSTRIES, LTD., Osaka-shi (JP)

(21) Appl. No.: 13/862,540

(22) Filed: Apr. 15, 2013

(30) Foreign Application Priority Data
Jun. 7, 2012 (JP) 2012-129958

(51) Int. Cl. C30B 23/02

(52) U.S. Cl. CPC C30B 23/02
USPC 117/84

(57) ABSTRACT

There is provided a method for producing a silicon carbide crystal, including the steps of: preparing a mixture by mixing silicon small pieces and carbon powders with each other; preparing a silicon carbide powder precursor by heating the mixture to not less than 2000° C. and not more than 2500° C.; preparing silicon carbide powders by pulverizing the silicon carbide powder precursor; and growing a silicon carbide crystal on a seed crystal using the silicon carbide powders in accordance with a sublimation-recrystallization method, 50% or more of the silicon carbide powders used in the step of growing the silicon carbide crystal having a polytype of 6H.

### BACKGROUND OF THE INVENTION

1. Field of the Invention

The present invention relates to a method for producing a silicon carbide crystal.

2. Description of the Background Art

In recent years, silicon carbide (SiC) single crystals have begun to be employed as semiconductor substrates for use in manufacturing semiconductor devices. SiC has a band gap larger than that of silicon (Si), which has been used more commonly. Hence, a semiconductor device employing SiC advantageously has a large breakdown voltage, low on-resistance, and properties less likely to decrease in a high temperature environment.

For example, Patent Literature 1 (Japanese Patent No. 4427470) discloses a method for producing a SiC single crystal having a polytype of 4H in the following manner. That is, high-purity carbon powders adapted to have a boron concentration of 0.11 ppm through heat treatment of 2000° C. or more in halogen gas are mixed with a silicon source material having a boron concentration lower than that of the carbon source material, so as to prepare a source material for growth of SiC single crystal. Then, a normal sublimation-recrystallization method is performed using a seed crystal and the prepared source material for growth of a SiC single crystal (for example, see paragraphs [0019] and [0020] of Patent Literature 1).

### SUMMARY OF THE INVENTION

However, in the method described in paragraphs [0019] and [0020] of Patent Literature 1, the growth rate of the SiC single crystal is very low and therefore the SiC single crystal cannot be efficiently produced, disadvantageously.

In view of the above, the present invention has its object to provide a method for producing a silicon carbide crystal so as to achieve improved growth rate of a silicon carbide crystal.

The present invention provides a method for producing a silicon carbide crystal, comprising the steps of: preparing a mixture by mixing silicon small pieces and carbon powders with each other; preparing a silicon carbide powder precursor by heating the mixture to not less than 2000° C. and not more than 2500° C.; preparing silicon carbide powders by pulverizing the silicon carbide powder precursor; and growing a silicon carbide crystal on a seed crystal using the silicon carbide powders in accordance with a sublimation-recrystallization method, 50% or more of the silicon carbide powders used in the step of growing the silicon carbide crystal having a polytype of 6H.

Here, in the method for producing the silicon carbide crystal in the present invention, 80% or more of the silicon carbide powders used in the step of growing the silicon carbide crystal preferably has the polytype of 6H.

According to the present invention, there can be provided a method for producing a silicon carbide crystal so as to achieve improved growth rate of a silicon carbide crystal.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross sectional view illustrating a part of a production process in one exemplary method for producing a silicon carbide crystal in the present invention.

FIG. 2 is a schematic plan view of one exemplary silicon small piece used in the present invention.

FIG. 3 is a schematic plan view of one exemplary silicon carbide powder precursor prepared in a step of preparing a silicon carbide powder precursor in the present invention.

FIG. 4 is a schematic cross sectional view illustrating a step of growing a silicon carbide crystal in the present invention.

FIG. 5 shows a profile of each of a temperature of a graphite crucible and a pressure in an electric furnace relative to a time having elapsed in preparation of silicon carbide powder A.

### DESCRIPTION OF THE PREFERRED EMBODIMENTS

The following describes one exemplary method for producing silicon carbide powders for growth of a silicon carbide crystal in the present invention. It should be noted that other step(s) may be included to come before or after each of steps described below.

<Step of Preparing Mixture>

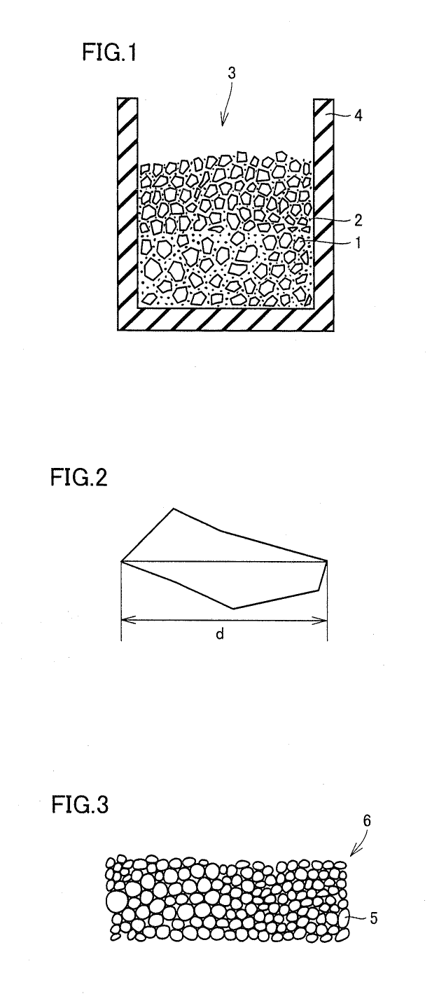

Performed first is a step of preparing a mixture 3 by mixing silicon small pieces 1 and carbon powders 2 as shown in a schematic cross sectional view of FIG. 1. The step of preparing mixture 3 can be performed by, for example, introducing silicon small pieces 1 and carbon powders 2 into a graphite crucible 4 and mixing them in graphite crucible 4 to prepare mixture 3. Alternatively, mixture 3 may be prepared by mixing silicon small pieces 1 and carbon powders 2 before introducing them into graphite crucible 4.

Here, as each of silicon small pieces 1, for example, it is preferable to use a silicon small piece 1 having a diameter d, which is shown in a schematic plan view of FIG. 2, of not less than 0.1 mm and not more than 5 cm. It is more preferable to use a silicon small piece 1 having a diameter d of not less than 1 mm and not more than 1 cm. In this case, a high-purity silicon carbide powder formed of silicon carbide up to its inside tends to be obtained. It should be noted that the term “diameter” herein is intended to mean the length of the longest one of line segments connecting two points in the surface thereof.

As carbon powders 2, it is preferable to use carbon powders having an average grain diameter (average value of respective diameters of carbon powders 2) of not less than 10 μm and not more than 200 μm. In this case, a high-purity silicon carbide powder composed of silicon carbide to its inside tends to be obtained.

<Step of Preparing Silicon Carbide Powder Precursor>

Performed next is the step of preparing a silicon carbide powder precursor by heating mixture 3 prepared as described above, to not less than 2000° C. and not more than 2500° C. The step of preparing the silicon carbide powder precursor can be performed by heating mixture 3, which includes silicon small pieces 1 and carbon powders 2 and is contained in graphite crucible 4 as described above, to a temperature of not less than 2000° C. and not more than 2500° C. under an inert gas atmosphere with a pressure of not less than 1 kPa and not more than 1.02×10⁵ Pa, in particular, not less than 10 kPa and not more than 70 kPa, for example. Accordingly, in graphite crucible 4, silicon of silicon small pieces 1 and carbon of carbon powders 2 react with each other to form silicon carbide, which is a compound of silicon and carbon. In this way, the silicon carbide powder precursor is prepared.

Here, if the heating temperature is smaller than 2000° C., the reaction of silicon and carbon does not proceed to reach the inside thereof because the heating temperature is too low. This results in failure of preparing a high-purity silicon carbide powder precursor formed of silicon carbide up to its inside. In contrast, if the heating temperature exceeds 2500° C., the reaction of silicon and carbon proceeds too much to thereby desorb silicon from silicon carbide formed by the reaction of silicon and carbon because the heating temperature is too high. This results in failure of preparing a high-purity silicon carbide powder precursor formed of silicon carbide up to its inside.

In the description above, as the inert gas, there can be used a gas including at least one selected from a group consisting of argon, helium, and nitrogen, for example.

Further, mixture 3 of silicon small pieces 1 and carbon powders 2 is preferably heated for not less than 1 hour and not more than 100 hours. In this case, the reaction of silicon and carbon can be likely to be sufficiently done, thereby preparing an excellent silicon carbide powder precursor.

Further, it is preferable to perform the step of decreasing the pressure of the atmosphere after the above-described heating. In this case, silicon carbide is likely to be formed up to the inside of each of below-described silicon carbide crystal grains constituting the silicon carbide powder precursor.

Here, in the case where the pressure of the atmosphere is decreased to a pressure of 10 kPa or smaller in the step of decreasing the pressure of the atmosphere, it preferably takes 10 hours or shorter to decrease the pressure, more preferably takes 5 hours or shorter, and further preferably takes 1 hour or shorter. When the pressure is decreased for 10 hours or shorter, more preferably 5 hours or shorter, in particular, 1 hour or shorter, the desorption of silicon from the silicon carbide formed by the reaction of silicon and carbon can be suitably suppressed, whereby an excellent silicon carbide powder precursor can be likely to be prepared.

Further, after decreasing the pressure of the atmosphere to a pressure of 10 kPa or smaller as described above, the pressure of the atmosphere may be increased to a pressure of 50 kPa or greater by supplying an inert gas thereto and then the silicon carbide powder precursor may be cooled to a room temperature (25° C.). Alternatively, with the pressure being maintained at 10 kPa or smaller, the silicon carbide powder precursor may be cooled to the room temperature (25° C.).

FIG. 3 shows a schematic plan view of one example of the silicon carbide powder precursor prepared by the step of preparing the silicon carbide powder precursor. Here, silicon carbide powder precursor 6 is constituted of an aggregate of the plurality of individual silicon carbide crystal grains 5 connected to one another.

<Step of Preparing Silicon Carbide Powder>

Performed next is the step of preparing silicon carbide powders by pulverizing silicon carbide powder precursor 6 prepared as described above. The step of preparing the silicon carbide powders can be performed by pulverizing silicon carbide powder precursor 6, which is the aggregate of the plurality of silicon carbide crystal grains 5 shown in FIG. 3, using a single-crystal or polycrystal silicon carbide ingot or a tool coated with silicon carbide of single-crystal or polycrystal, for example.

If silicon carbide powder precursor 6 is pulverized using an object other than the silicon carbide single-crystal or polycrystal, it is preferable to clean the silicon carbide powders using an acid including at least one selected from a group consisting of hydrochloric acid, aqua regia, and hydrofluoric acid, for example. For example, if silicon carbide powder precursor 6 is pulverized using an object made of steel, metal impurities such as iron, nickel, and cobalt are likely to be mixed in or adhered to the silicon carbide powders thus obtained by the pulverization. In order to remove such metal impurities, it is preferable to clean them using the above-described acid.

Not only the surface but also the inside of each of the silicon carbide powders prepared as described above are highly likely to be formed of silicon carbide. Hence, the silicon carbide powder is substantially composed of silicon carbide. It should be noted that the expression “substantially composed of silicon carbide” is intended to mean that 99 mass % or greater of the silicon carbide powder is formed of silicon carbide.

For example, in the source material prepared by the conventional method described in Patent Literature 1, the content of impurity formed of carbon existing as a simple substance in the surface portion is small, but the content of carbon existing as a simple substance in the surface portion and the inside thereof is greater than 50 mass %. In Patent Literature 1, only the surface of the source material was analyzed using the X-ray diffraction method, and the inside thereof was not analyzed using the X-ray diffraction method with increased X-ray penetration depths. Hence, in Patent Literature 1 of the conventional art, it has not been noticed that carbon existed as a simple substance because the reaction of silicon and carbon had not proceeded to the inside of the source material prepared by the conventional method described in Patent Literature 1.

As compared with the source material prepared by the conventional method described in Patent Literature 1, the reaction proceeds to form silicon carbide up to the inside of the silicon carbide powders prepared as described above. Accordingly, each of the silicon carbide powders can be substantially composed of silicon carbide. Thus, the silicon carbide powder prepared as described above can be a silicon carbide powder containing high-purity silicon carbide.

Because the silicon carbide powder prepared as described above is substantially composed of the silicon carbide as described above, the content of boron can be 0.5 ppm or smaller and the content of aluminum can be 1 ppm or smaller in the silicon carbide powder. Specifically, the content of boron in the silicon carbide powder prepared as described above is 0.00005 mass % or smaller of the entire silicon carbide powder, and the content of aluminum therein is 0.0001 mass % or smaller of the entire silicon carbide powder.

Further, 50% or more, preferably, 80% or more of the silicon carbide powders prepared as described above have a polytype of 6H. By using such silicon carbide powders including the silicon carbide powders having a polytype of 6H by 50% or more, preferably 80% or more, improved growth rate of the silicon carbide crystal is achieved in the below-described step of growing the silicon carbide crystal.

It should be noted that the content (%) of the silicon carbide powders having a polytype of 6H can be calculated by subjecting the silicon carbide powders to a powder X-ray diffraction method (θ-2θ scan), in accordance with the following formula (I):

The content(%)of the silicon carbide powders having a polytype of 6H=100×{(a magnitude of X-ray diffraction peak strength for the polytype of 6H)/(a total of magnitudes of X-ray diffraction peak strengths for all the polytypes)} (I)

Exemplary polytypes other than the polytype of 6H in the silicon carbide powders include 15R, 4H, and the like.

Further, the average grain diameter of the silicon carbide powders prepared as described above is preferably not less than 10 μm and not more than 2 mm. When the average grain diameter of the silicon carbide powders is not less than 10 μm and not more than 2 mm, graphite crucible 4 can be filled with the silicon carbide powders at a high filling ratio for crystal growth of silicon carbide crystal and the rate of silicon carbide crystal growth can be increased in the below-described step of growing the silicon carbide crystal. It should be noted that the term “average grain diameter of the silicon carbide powders” is intended to mean an average value of respective diameters of the individual silicon carbide powders.

<Step of Growing Silicon Carbide Crystal>

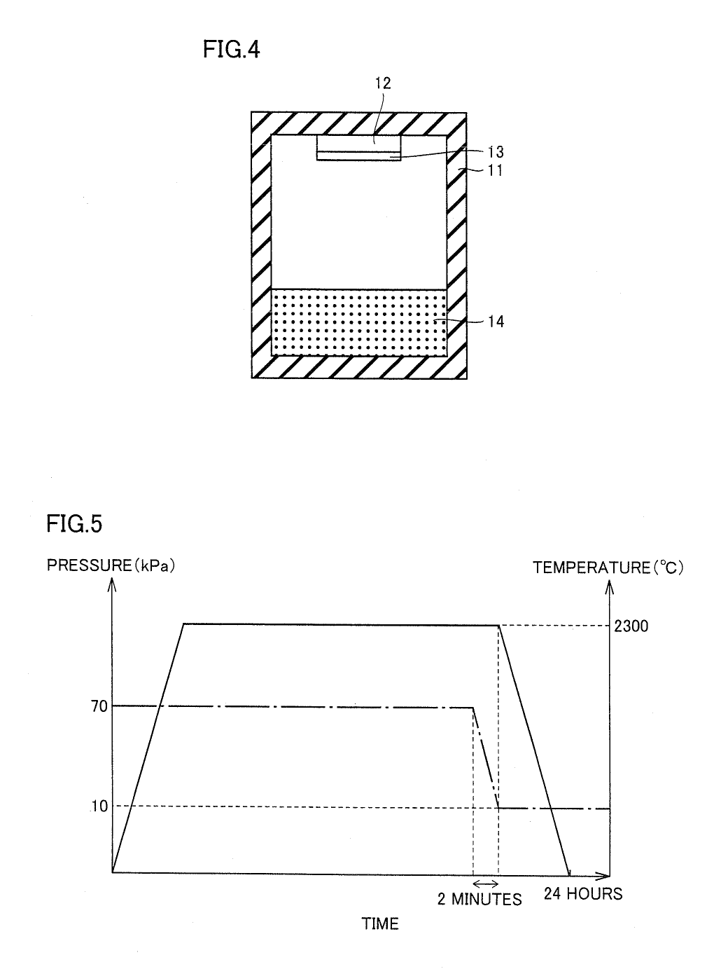

Performed next is the step of growing the silicon carbide crystal on a seed crystal using the silicon carbide powders prepared as described above, by means of the sublimation-recrystallization method. First in the step of growing the silicon carbide crystal, for example, as shown in a schematic cross sectional view of FIG. 4, silicon carbide powders 14 are placed at a lower portion of crucible 11 and seed crystal 12 is placed at the upper portion of crucible 11. Then, a temperature of the lower portion of crucible 11 is set. Then, a temperature of the upper portion of crucible 11 is set to be lower than the temperature of the lower portion. In this way, silicon carbide crystal 13 can be grown on the surface of seed crystal 12.

Here, the temperature of the lower portion of crucible 11 can be set at, for example, approximately 2300° C., whereas the temperature of the upper portion of crucible 11 can be set at, for example, approximately 2200° C.

<Function and Effect>

In the method for producing the silicon carbide crystal in the present invention, the silicon carbide crystal is grown on the seed crystal in accordance with the sublimation-recrystallization method, using the silicon carbide powders including the silicon carbide powders having a polytype of 6H by 50% or more, preferably, 80% or more. Accordingly, the growth rate of the silicon carbide crystal can be increased as compared with the conventional method described in Patent Literature 1.

### EXAMPLES

### Preparation of Silicon Carbide Powders A

First, as the silicon small pieces, a plurality of silicon small pieces were prepared each of which had a diameter of not less than 1 mm and not more than 1 cm. As the carbon powders, carbon powders were prepared which had an average grain diameter of 200 μm. Here, each of the silicon small pieces was a silicon chip having a purity of 99.999999999% for silicon single-crystal pulling.

Next, 154.1 g of the silicon small pieces and 65.9 g of the carbon powders were lightly mixed to obtain a mixture, which was then introduced into a graphite crucible. The graphite crucible used here had been heated in advance to 2300° C. in a high-frequency heating furnace under argon gas with a reduced pressure of 0.013 Pa, and had been held for 14 hours.

Next, the graphite crucible having the mixture of the silicon small pieces and the carbon powders therein as described above was put in an electric heating furnace, and was vacuumed to 0.01 Pa. The atmosphere was then substituted with argon gas having a purity of 99.9999% or greater to achieve a pressure of 70 kPa in the electric furnace.

Next, as shown in FIG. 5, with the pressure being maintained at 70 kPa in the electric furnace, the graphite crucible containing the mixture of the silicon small pieces and the carbon powders were heated to 2300° C. and held at this temperature for 20 hours. Thereafter, the pressure in the electric furnace was reduced to 10 kPa within 2 minutes. Thereafter, the temperature of the graphite crucible was decreased to a room temperature (25° C.). FIG. 5 shows a profile of the temperature of the graphite crucible and the pressure in the electric furnace relative to elapsed time. It should be noted that in FIG. 5, a solid line represents a change of the temperature of the graphite crucible, and a dashed line represents a change of the pressure in the electric furnace.

Next, a silicon carbide powder precursor prepared by the above-described heat treatment was taken out from the graphite crucible. Here, as a result of observing the silicon carbide powder precursor, the silicon carbide powder precursor was found to be constituted of an aggregate of a plurality of individual silicon carbide crystal grains connected to one another.

Next, the silicon carbide powder precursor obtained as described above was pulverized using a tool coated with a silicon carbide polycrystal, thereby preparing silicon carbide powders A. Here, silicon carbide powders A had an average grain diameter of 20 μm.

Silicon carbide powders A obtained as described above were subjected to qualitative analysis by means of a powder X-ray diffraction method. With Cu being set as a target for the X ray, the penetration depth of the X ray can be 10 μm or greater. Accordingly, components constituting the inside of each silicon carbide powder A can be specified.

As a result of performing qualitative analysis and quantitative analysis (simple quantitative measurement) on the components of silicon carbide powder A using the above-described powder X-ray diffraction method (θ-2θ scan), it was confirmed that a ratio of an integrated value of an X-ray diffraction peak indicating existence of C relative to a total of integrated values of X-ray diffraction peaks respectively corresponding to all the components constituting silicon carbide powder A (100×(the integrated value of the X-ray diffraction peak indicating existence of C)/(the total of the integrated values of the X-ray diffraction peaks respectively corresponding to all the components constituting silicon carbide powder A)) was smaller than 1%. It was also confirmed that a ratio of an integrated value of an X-ray diffraction peak indicating existence of SiC relative to the total of integrated values of the X-ray diffraction peaks respectively corresponding to all the components constituting silicon carbide powder A (100×(the integrated value of the X-ray diffraction peak indicating existence of SiC)/(the total of the integrated values of the X-ray diffraction peaks respectively corresponding to all the components constituting silicon carbide powder A)) was 99% or greater. Thus, it is considered that silicon carbide powder A was a high-purity silicon carbide powder substantially completely formed of silicon carbide up to its inside (silicon carbide at a content of 99 mass % or greater) and containing carbon existing as a simple substance at a content of less than 1 mass %.

In addition, silicon carbide powder A was evaluated using a glow discharge mass spectrometry (GDMS) method. As a result, it was confirmed that the content of boron was 0.5 ppm or smaller and the content of aluminum was 1 ppm or smaller in silicon carbide powder A.

Further, silicon carbide powders A were sieved to have a grain diameter distribution of 500 μm to 1000 μm. Then, the content (%) of the silicon carbide powders having a polytype of 6H was calculated using the powder X-ray diffraction method (θ-2θ scan), in accordance with the above-described formula (I). As a result, the content (%) of the silicon carbide powders having a polytype 6H in silicon carbide powders A was 85%.

<Preparation of Silicon Carbide Powders B>

Silicon carbide powders B were prepared in the same way as silicon carbide powers A except that the pressure in the electric furnace was not reduced, and then were subjected to qualitative analysis and quantitative analysis using the powder X-ray diffraction method under the same conditions as those for silicon carbide powders A.

As a result, it was confirmed that a ratio of an integrated value of an X-ray diffraction peak indicating existence of C relative to a total of integrated values of X-ray diffraction peaks respectively corresponding to all the components constituting silicon carbide powder B was smaller than 1%. It was also confirmed that a ratio of an integrated value of an X-ray diffraction peak indicating existence of SiC relative to the total of integrated values of the X-ray diffraction peaks respectively corresponding to all the components constituting silicon carbide powder B was 99% or greater. Thus, it is considered that silicon carbide powder B was also a high-purity silicon carbide powder substantially completely formed of silicon carbide up to its inside (silicon carbide at a content of 99 mass % or greater) and containing carbon existing as a simple substance at a content of less than 1 mass %.

In addition, silicon carbide powder B was evaluated using a glow discharge mass spectrometry (GDMS) method. As a result, it was confirmed that the content of boron was 0.5 ppm or smaller and the content of aluminum was 1 ppm or smaller in silicon carbide powder B.

Further, silicon carbide powders B were sieved to have a grain diameter distribution of 500 μm to 1000 μm. Then, the content (%) of the silicon carbide powders having a polytype of 6H was calculated using the powder X-ray diffraction method (θ-2θ scan), in accordance with the above-described formula (I). As a result, the content (%) of the silicon carbide powders having a polytype 6H in silicon carbide powders B was 52%.

<Preparation of Silicon Carbide Powders C>

Silicon carbide powders C were prepared in the same way as silicon carbide powders A except that the heating temperature of the graphite crucible was set at 2000° C., and then were subjected to qualitative analysis and quantitative analysis using the powder X-ray diffraction method under the same conditions as those for silicon carbide powders A.

As a result, it was confirmed that a ratio of an integrated value of an X-ray diffraction peak indicating existence of C relative to a total of integrated values of X-ray diffraction peaks respectively corresponding to all the components constituting silicon carbide powder C was smaller than 1%. It was also confirmed that a ratio of an integrated value of an X-ray diffraction peak indicating existence of SiC relative to the total of integrated values of the X-ray diffraction peaks respectively corresponding to all the components constituting silicon carbide powder C was 99% or greater. Thus, it is considered that silicon carbide powder C was also a high-purity silicon carbide powder substantially completely formed of silicon carbide up to its inside (silicon carbide at a content of 99 mass % or greater) and containing carbon existing as a simple substance at a content of less than 1 mass %.

In addition, silicon carbide powder C was evaluated using the glow discharge mass spectrometry (GDMS) method. As a result, it was confirmed that the content of boron was 0.5 ppm or smaller and the content of aluminum was 1 ppm or smaller in silicon carbide powder C.

Further, silicon carbide powders C were sieved to have a grain diameter distribution of 500 μm to 1000 μm. Then, the content (%) of the silicon carbide powders having a polytype of 6H was calculated using the powder X-ray diffraction method (θ-2θ scan), in accordance with the above-described formula (I). As a result, the content (%) of the silicon carbide powders having a polytype 6H in silicon carbide powders C was 85%.

<Preparation of Silicon Carbide Powders D>

Silicon carbide powders D were prepared in the same way as silicon carbide powders A except that the heating temperature of the graphite crucible was set at 2500° C., and then were subjected to qualitative analysis and quantitative analysis using the powder X-ray diffraction method under the same conditions as silicon carbide powders A.

As a result, it was confirmed that a ratio of an integrated value of an X-ray diffraction peak indicating existence of C relative to a total of integrated values of X-ray diffraction peaks respectively corresponding to all the components constituting silicon carbide powder D was smaller than 1%. It was also confirmed that a ratio of an integrated value of an X-ray diffraction peak indicating existence of SiC relative to the total of integrated values of the X-ray diffraction peaks respectively corresponding to all the components constituting silicon carbide powder D was 99% or greater. Thus, it is considered that silicon carbide powder D was also a high-purity silicon carbide powder substantially completely formed of silicon carbide up to its inside (silicon carbide at a content of 99 mass % or greater) and containing carbon existing as a simple substance at a content of less than 1 mass %.

In addition, silicon carbide powder D was evaluated using the glow discharge mass spectrometry (GDMS) method. As a result, it was confirmed that the content of boron was 0.5 ppm or smaller and the content of aluminum was 1 ppm or smaller in silicon carbide powder D.

Further, silicon carbide powders D were sieved to have a grain diameter distribution of 500 μm to 1000 μm. Then, the content (%) of the silicon carbide powders having a polytype of 6H was calculated using the powder X-ray diffraction method (θ-2θ scan), in accordance with the above-described formula (I). As a result, the content (%) of the silicon carbide powders having a polytype 6H in silicon carbide powders D was 85%.

<Preparation of Silicon Carbide Powders E>

First, as a carbon source material, high-purity carbon powders having been through heat treatment at 2000° C. or greater in halogen gas were prepared. As a silicon source material, silicon chips each having a purity of 99.999999999% for silicon single crystal pulling were prepared.

Here, the carbon source material was subjected to pretreatment as follows: the carbon source material was introduced into a graphite crucible, was heated together with the graphite crucible to about 2200° C. in a high-frequency heating furnace under argon gas with a reduced pressure of 0.013 Pa, and was held for 15 hours in advance.

It should be noted that boron concentrations of the carbon source material and the silicon source material both having been through the above-described pretreatment were measured by means of the glow discharge mass spectrometry (GDMS) and were found to be 0.11 ppm and 0.001 ppm or smaller respectively.

Meanwhile, the silicon chips, which were the silicon source material, mainly were several mm to ten several mm in size. The carbon source material having been through the pretreatment had an average grain diameter of 92 μm.

Next, 65.9 g of the carbon source material and 154.1 g of the silicon source material were lightly mixed, and mixed powders of the carbon source material and the silicon source material were introduced into the above-described graphite crucible.

Next, the graphite crucible thus containing the carbon source material and the silicon source material was put in an electric heating furnace. Then, pressure in the electric furnace was vacuumed to 0.01 Pa. Thereafter, the atmosphere was substituted with argon gas having a purity of 99.9999% or greater to achieve a pressure of 80 kPa in the electric furnace. While adjusting the pressure in this electric furnace, heating was performed to 1420° C., which was then held for 2 hours. Thereafter, further heating was performed to 1900° C., which was then held for 3 hours. Thereafter, the temperature was decreased.

Silicon carbide powders E obtained as described above were subjected to qualitative analysis and quantitative analysis using the powder X-ray diffraction method under the same conditions as those for silicon carbide powders A.

As a result, it was confirmed that a ratio of an integrated value of an X-ray diffraction peak indicating existence of C relative to a total of integrated values of X-ray diffraction peaks respectively corresponding to all the components constituting silicon carbide powder E was greater than 50%. Hence, it is considered that the inside of silicon carbide powder E was almost formed of carbon and the content of carbon existing as a simple substance was greater than 50 mass %.

Further, silicon carbide powders E were sieved to have a grain diameter distribution of 500 μm to 1000 μm. Then, the content (%) of the silicon carbide powders having a polytype of 6H was calculated using the powder X-ray diffraction method (θ-2θ scan), in accordance with the above-described formula (I). As a result, the content (%) of the silicon carbide powders having a polytype 6H in silicon carbide powders E was 17%.

<Preparation of Silicon Carbide Powders F>

Silicon carbide powders F were prepared in the same way as silicon carbide powders A except that the heating temperature of the graphite crucible was set at 1950° C., and then were subjected to qualitative analysis and quantitative analysis using the powder X-ray diffraction method under the same conditions as those for silicon carbide powders A.

As a result, it was confirmed that a ratio of an integrated value of an X-ray diffraction peak indicating existence of C relative to a total of integrated values of X-ray diffraction peaks respectively corresponding to all the components constituting silicon carbide powder F was greater than 50%. Hence, it is considered that the inside of silicon carbide powder F was almost formed of carbon and the content of carbon existing as a simple substance was greater than 50 mass %. This is presumably because the heating temperature of the graphite crucible was too low, with the result that the reaction of silicon and carbon did not proceed to the inside thereof.

Further, silicon carbide powders F were sieved to have a grain diameter distribution of 500 μm to 1000 μm. Then, the content (%) of the silicon carbide powders having a polytype of 6H was calculated using the powder X-ray diffraction method (θ-2θ scan), in accordance with the above-described formula (I). As a result, the content (%) of the silicon carbide powders having a polytype 6H in silicon carbide powders F was 17%.

<Preparation of Silicon Carbide Powders G>

Silicon carbide powders G were prepared in the same way as silicon carbide powders A except that the heating temperature of the graphite crucible was set at 2550° C., and then were subjected to qualitative analysis and quantitative analysis using the powder X-ray diffraction method under the same conditions as those for silicon carbide powders A.

As a result, it was confirmed that a ratio of an integrated value of an X-ray diffraction peak indicating existence of C relative to a total of integrated values of X-ray diffraction peaks respectively corresponding to all the components constituting silicon carbide powder G was greater than 50%. Hence, it is considered that the inside of silicon carbide powder G was also almost formed of carbon and the content of carbon existing as a simple substance was greater than 50 mass %. This is presumably because the heating temperature of the graphite crucible is too high, with the result that silicon was desorbed from silicon carbide generated by the reaction of silicon and carbon.

Further, silicon carbide powders G were sieved to have a grain diameter distribution of 500 μm to 1000 μm. Then, the content (%) of the silicon carbide powders having a polytype of 6H was calculated using the powder X-ray diffraction method (θ-2θ scan), in accordance with the above-described formula (I). As a result, the content (%) of the silicon carbide powders having a polytype 6H in silicon carbide powders G was 17%.

### Example 1

First, at an upper portion of a crucible made of graphite and having an inner diameter of 160 mm and a depth of 180 mm, a 4H type SiC single crystal having a diameter of 150 mm was prepared as a seed crystal (the SiC single crystal had a surface corresponding to a C plane, off by 4° relative to a plane orientation of (000-1) in a <11-20> direction, and subjected to CMP (Chemical Mechanical Polishing)). At a lower portion of the crucible made of graphite, 3500 g of silicon carbide powders A prepared as described above was placed as a source material (to a depth 10 cm).

It should be noted that when indicating crystal plane and direction, a bar is supposed to be put above a numeral, but in the present specification, “-” is put before the numeral instead of putting a bar above the numeral due to restriction on expression.

Next, a heat insulating material (molded heat insulating material made of graphite) was placed at the outer circumference of the crucible made of graphite. Then, they were placed in a high-frequency heating furnace.

Next, evacuation was performed to attain a pressure of less than 1 Pa in the crucible made of graphite. Thereafter, argon gas containing nitrogen gas by 10 volume % was introduced into the crucible made of graphite so as to attain a pressure of 90 kPa in the crucible made of graphite.

Next, the temperature of the upper portion of the crucible made of graphite was set at 2200° C. and the temperature of the lower portion of the crucible made of graphite was increased to 2300° C. Thereafter, the pressure in the crucible made of graphite was decreased to 1 kPa for 1 hour. In this way, a silicon carbide crystal having a polytype of 4H was grown on the seed crystal for 200 hours. Thereafter, the silicon carbide crystal thus grown was cooled and then was taken out from the crucible made of graphite.

Table 1 shows a growth rate of the silicon carbide crystal grown on the seed crystal, and a height of the silicon carbide crystal recrystallized on the surface of silicon carbide powders A serving as the source material in Example 1.

As shown in Table 1, in Example 1, the growth rate of the silicon carbide crystal grown on the seed crystal was 0.2 mm/h, and the height of the silicon carbide crystal recrystallized on the surface of silicon carbide powders A serving as the source material was 1 cm.

### Example 2

A silicon carbide crystal having a polytype of 4H was grown on a seed crystal in the same manner as in Example 1 except that silicon carbide powders B were used as the source material instead of silicon carbide powders A.

Table 1 shows a growth rate of the silicon carbide crystal grown on the seed crystal, and a height of the silicon carbide crystal recrystallized on the surface of silicon carbide powders B serving as the source material in Example 2.

As shown in Table 1, in Example 2, the growth rate of the silicon carbide crystal grown on the seed crystal was 0.18 mm/h, and the height of the silicon carbide crystal recrystallized on the surface of silicon carbide powders B serving as the source material was 2 cm.

### Comparative Example 1

A silicon carbide crystal having a polytype of 4H was grown on a seed crystal in the same manner as in Example 1 except that silicon carbide powders E were used as the source material instead of silicon carbide powders A.

Table 1 shows a growth rate of the silicon carbide crystal grown on the seed crystal, and a height of the silicon carbide crystal recrystallized on the surface of silicon carbide powders E serving as the source material in Comparative Example 1.

As shown in Table 1, in Comparative Example 1, the growth rate of the silicon carbide crystal grown on the seed crystal was 0.05 mm/h, and the height of the silicon carbide crystal recrystallized on the surface of silicon carbide powders E serving as the source material was 5 cm.

TABLE 1

| | | | Comparative |
|---|---|---|---|
| | Example 1 | Example 2 | Example 1 |
| Content of Silicon Carbide | 85 | 52 | 17 |
| Powders having Polytype of | | | |
| 6H (%) | | | |
| Growth Rate of Silicon | 0.2 | 0.18 | 0.05 |
| Carbide Crystal Grown on | | | |
| Seed Crystal (mm/h) | | | |
| Height of Silicon Carbide | 1 | 2 | 5 |
| Crystal Recrystallized on | | | |
| Surface of Silicon Carbide | | | |
| Powders Serving as Source | | | |
| Material (cm) | | | |

<Evaluation>

In each of Example 1 and Example 2, the silicon carbide crystal was grown on the seed crystal in accordance with the sublimation-recrystallization method, using the silicon carbide powders containing silicon carbide powders having a polytype of 6H at a content of 50% or more. As shown in Table 1, it was confirmed that the growth rate of the silicon carbide crystal grown on the seed crystal in each of Example 1 and Example 2 became higher than that in Comparative Example 1 in which the content of the silicon carbide powders having a polytype of 6H was 17%.

In particular, it was confirmed that the highest growth rate of the silicon carbide crystal grown on the seed crystal was achieved in Example 1 in which the silicon carbide crystal was grown on the seed crystal in accordance with the sublimation-recrystallization method using the silicon carbide powders containing the silicon carbide powders having a polytype of 6H at a content of 80% or more.

Meanwhile, in Comparative Example 1, recystallization of porous silicon carbide polycrystal became noticeable on the surface of silicon carbide powders E serving as the source material, with the result that the silicon carbide polycrystal recrystallized on the surface of silicon carbide powders E serving as the source material was substantially in contact with the silicon carbide crystal having a polytype of 4H grown on the seed crystal.

In addition, because the source material gas was presumably consumed for the recystallization of the silicon carbide polycrystal in Comparative Example 1, the growth rate of the silicon carbide crystal grown on the seed crystal was significantly decreased.

On the other hand, in each of Example 1 and Example 2, it is considered that the recystallization of the silicon carbide polycrystal was suppressed, so that the growth rate of the silicon carbide crystal grown on the seed crystal was not decreased.

It should be noted that the above-described phenomenon is considered to be noticeable when the diameter of the silicon carbide crystal is adapted to be large, specifically, to exceed 4 inches, moreover, to reach 6 inches.

The present invention can be suitably employed for a method for producing a silicon carbide crystal.

Heretofore, the embodiments and examples of the present invention have been illustrated, but it has been initially expected to appropriately combine configurations of the embodiments and examples.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method for producing a silicon carbide crystal, comprising the steps of:
preparing a mixture by mixing silicon small pieces and carbon powders with each other;
preparing a silicon carbide powder precursor by heating said mixture to not less than 2000° C. and not more than 2500° C.;
preparing silicon carbide powders by pulverizing said silicon carbide powder precursor; and
growing a silicon carbide crystal on a seed crystal using said silicon carbide powders in accordance with a sublimation-recrystallization method, 50% or more of said silicon carbide powders used in the step of growing said silicon carbide crystal having a polytype of 6H.

2. The method for producing the silicon carbide crystal according to claim 1, wherein 80% or more of said silicon carbide powders used in the step of growing said silicon carbide crystal has the polytype of 6H.
